(19) United States
(12) Patent Application Publication
(10) Pub. No.: US 2008/0295909 A1
(43) Pub. Date: Dec. 4, 2008

(54) Microfluidic Device for Passive Sorting and Storage of Liquid Plugs Using Capillary Force

(76) Inventors: Laurie E. Locascio, North Potomac, MD (US); Francisco Javier Atencia-Fernandez, Bethesda, MD (US); Susan Barnes, Raleigh, NC (US)

Correspondence Address: BOYLE FREDRICKSON S.C., 840 North Plankinton Avenue, MILWAUKEE, WI, 53203, US

(21) Appl. No.: 12/127,328

(22) Filed: May 27, 2008

Related U.S. Application Data
(60) Provisional application No. 60/939,939, filed on May 24, 2007.

(51) Int. Cl. F15C 1/06; B01L 3/00; B81B 1/00

(52) U.S. Cl. 137/833; 422/100; 422/101

(57) ABSTRACT

A three dimensional microfluidic device for passive sorting and storing of liquid plugs is provided with homogeneous surfaces from the exposure of a photopolymer through binary masking motifs, i.e., arrays of opaque pixels on a transparency mask. The device includes sub-millimeter three-dimensional relief microstructures to aid in the channeling of fluids. The microstructures have topographically modulated features smaller than 100 micrometers.

### CROSS-REFERENCE TO RELATED APPLICATION

This application claims a benefit of priority under 35 USC § 119 based on patent application 60/939,944, filed May 24, 2007, the entire contents of which are hereby expressly incorporated by reference into the present application.

### STATEMENT AS TO RIGHTS TO INVENTION(S) MADE UNDER FEDERALLY-SPONSORED RESEARCH AND DEVELOPMENT

The U.S. Government, through the National Institute of Standards and Testing, is the owner of this invention.

### BACKGROUND OF THE INVENTION

1. Field of the Invention

The present invention relates in general to the field of microfluidics. More particularly, the present invention relates to a three dimensional (3D) microfluidic device for the passive sorting and storage of liquid plugs using capillary force.

2. Discussion of the Related Art

Sorting and storing microfluidic droplets is a subject of high importance for a number of different applications. One field is protein crystallization. For example, the group of Prof Ismagilov at the University of Chicago creates droplets with different contents of the reagents necessary to crystallize proteins. In this approach, the contents of each droplet are modified to enable screening through a large combinatorial set of reactions to determine the best combination of reagents for protein crystals. After production, the droplets need to be stored in a deterministic way so that the contents of each stored droplet are known. The initial solution to the problem of sequential storage was to introduce a glass capillary on a microchannel, fill it with a sequence of droplets, take it out, seal it with wax, and connect a second capillary to the outlet of the device. This operation proved cumbersome as the capillaries needed to be filled sequentially, labeled, and then stored many times. More recently, a simpler way to perform this operation by running the generation of droplets into very long tubing until it was filled was demonstrated.

Another method to store sequentially droplets for combinatorial experiments has also been published. This other method involves using external active valves to fill the side channels.

Despite recent advances, the methods discussed above are still too limited for a large number of applications.

Therefore, what is needed is a microfluidic device that does not need active valves and has no storage limitation because it has as many side microchannels as desired. Further, what is needed is a microfluidic device in which the microchannels are geometrically designed to allow filling flow using solely capillary force, i.e., by passive pumping.

What is also needed is a device that could be used in a remote location or in a lab that has a variety of applications and many degrees of freedom.

Fabrication techniques for the current invention are generally discussed in the article entitled “Using Pattern Homogenization of Binary Grayscale Masks to Fabricate Microfluidic Structures with 3D Topography,” Lab Chip, 2007, 7, 1567-1573, which was published in August of 2007 by the Royal Society of Chemistry, the entire contents of which are hereby expressly incorporated by reference into the present application.

### SUMMARY AND OBJECTS OF THE INVENTION

By way of summary, the present invention is directed to microstructures with arbitrary topography. Preferably, the microstructures have modulated 3D topography over large areas (centimeters) and only require a single photolithographic step during fabrication. The device may further comprise at least one outlet in communication with the microchannel. The microchannel's topographic constrictions may be designed to stop priming flow through the main microchannel. These constrictions may further make use of capillary forces to move a liquid until a dead-end side channel is completely filled and a plug of liquid is stored therein. Any air (or gas) escapes through small orifices at the end of the side microchannels during this filling process. Subsequent plugs of liquid may be stored sequentially in the dead-end side channels of the device. In this way, the plugs of liquid may be used to create libraries of liquid plugs with arbitrary concentrations of chemicals. Additionally, the device may be designed to be primed passively with capillary forces.

The device may allow for complex chemical mixtures to be generated and stored for applications such as chemotaxis experiments under zero-flow conditions. The device may also allow for complex chemical mixtures to be dispersed in immiscible liquid forming droplets for combinatorial experiment or stored deterministically for subsequent analysis.

There are several possible applications of the device including the device being used in a remote location to sample water from a source. In such an application, this invention could be used for environmental sampling of liquids. For example, a person could bring one such device to a remote location and sample water from a source. The device could be designed to be primed passively with capillary forces (no external power would be required). This way the liquid sampled in the different side channels would correspond to samples acquired sequentially with a time lag between them.

This device could also be employed to realize combinatorial experiments in a lab. For example, droplets (or biological cells) could be introduced in different side channels according to a distinct property (e.g., different types of cells). The substrate could be functionalized with a gradient of proteins across the direction perpendicular to the channels, and/or with a gradient in temperature, light, etc. This device would work as a combinatorial platform with several degrees of freedom.

In another embodiment the invention is a microfluidic device without an actuator that is capable of sorting liquid plugs chronologically and storing them comprising: (1) a main microchannel with a multitude of topographic constrictions, (2) at least two inlets that merge into the main microchannel, (3) side channels with small orifices to allow any air (or gas) to escape that are associated with the topographic constrictions and alternate with the inlets, (4) and one outlet in communication with the main microchannel.

In another application of this embodiment, the device may provide for a gradient of proteins across a direction perpendicular to the channels. In another application possibly used in conjunction with the prior application, the device may also be used under zero gravity to handle liquid samples in space.

In yet another embodiment, the invention is a microfluidic device comprising a photoresist exposed to UV light through a binary transparency mask including an optical adhesive with low contrast γ≈0.55 to promote partial polymerization in areas subject to diffracted light and to facilitate the transfer of discrete patterns from the mask as homogeneous patterns (smooth surfaces) to the photoresist.

The device may comprise semicircular microchannels generated by using swatches of 5×1 pixels that are enlarged with graphic-design software to form lines. Additionally, complex curved surfaces in a microchannel may be created with graphic software operations such as stretching, rotating and skewing.

The device may further comprise a second microchannel of a smaller diameter that is semi-circular and includes a semi-spiral ridge inside. Microchannels may also have a zigzag structure that is modulated in an x, y and z direction.

These, and other aspects and objects of the present invention will be better appreciated and understood when considered in conjunction with the following description and the accompanying drawings. It should be understood, however, that the following description, while indicating preferred embodiments of the present invention, is given by way of illustration and not of limitation. Many changes and modifications may be made within the scope of the present invention without departing from the spirit thereof, and the invention includes all such modifications.

### BRIEF DESCRIPTION OF THE DRAWINGS

A clear conception of the advantages and features constituting the present invention, and of the construction and operation of typical mechanisms provided with the present invention, will become more readily apparent by referring to the exemplary, and therefore non-limiting, embodiments illustrated in the drawings accompanying and forming a part of this specification, wherein like reference numerals designate the same elements in the several views, and in which:

FIG. 1 is an illustration of morphology transition in an array of swatches of different pixels size and density;

FIG. 2 and the FIG. 3 illustrate various shapes produced;

FIG. 4 illustrates various grayscale tones in swatches which may be used;

FIG. 5 is a schematic illustrating fabrication of a master template;

FIG. 6 shows one embodiment of a microfluidic device of the present invention;

FIG. 7 is a close-up of a microchannel of the device shown in FIG. 6;

FIG. 8 is a grayscale pattern used to create the microchannel shown in FIG. 7;

FIG. 9 is a swatch used to create the grayscale pattern of FIG. 8;

FIGS. 10 and 11 are schematics of side channels of the device shown in FIG. 6;

FIGS. 12A and 12 B illustrate fluid flow in the device shown in FIG. 6;

FIG. 13 is a partial view of a grayscale pattern used to create a microfluidic device of the present invention;

FIG. 14 is a swatch used to create the grayscale pattern of FIG. 13;

FIG. 15 is a partial close-up view of microchannels of the device created using the grayscale shown in FIG. 13;

FIGS. 16A-17 B illustrate other grayscale patterns and the shapes may form;

FIG. 18 shows a partial view T-shaped microchannel of the present invention;

FIG. 19 shows a close up of a zigzag section of microchannel of the present invention;

FIG. 20 is a partial view of a grayscale used to create the microchannel of FIG. 19;

FIG. 21 is a swatch used to create the grayscale pattern of FIG. 20;

FIG. 22 shows a close-up of a concentric circle pattern of the present invention;

FIG. 23 is a pixelated grayscale pattern of FIG. 22;

FIG. 24 is a horn created using the pattern shown in the FIG. 23;

FIG. 25A is a master template of horns like the one shown in FIG. 24;

FIG. 25B shows a method of creating an ejector plate from the template shown in FIG. 25A;

FIG. 26 shows an ejector device of the present invention;

FIG. 27A is an illustration showing an ejector device in operation;

FIG. 27B is a photograph showing that ejector device of the present invention in operation;

FIG. 28 is a diagram showing the various pixel patterns and swatches that may be used to develop various microstructures of the present invention;

FIG. 29 is another diagram showing the various masks with pixel patterns that may be used to develop various microstructures of the present invention;

FIGS. 30 and 31 show a master template of a microstructure of the present invention;

FIGS. 32 and 33 show replicas created from the template shown in FIGS. 30 and 31; and

FIG. 34 is a graph showing a calculation of the present invention.

In describing the preferred embodiment of the invention that is illustrated in the drawings, specific terminology will be resorted to for the sake of clarity. However, it is not intended that the invention be limited to the specific terms so selected and it is to be understood that each specific term includes all technical equivalents that operate in a similar manner to accomplish a similar purpose. For example, the words “connected”, “attached”, or terms similar thereto are often used. They are not limited to direct connection but include connection through other elements where such connection is recognized as being equivalent by those skilled in the art.

### DESCRIPTION OF PREFERRED EMBODIMENTS

The present invention and the various features and advantageous details thereof are explained more fully with reference to the non-limiting embodiments described in detail in the following description.

### 1. System Overview

In the method of the present invention, first a glass slide is brought into contact with an optical adhesive of a photoresist chip. A mask with grayscale patterns is then used to block UV light selectively from the photoresist chip. This method promotes partial polymerization on the chip in areas subject to diffracted light. It also facilitates the transfer of discrete patterns from the mask to the photoresist chip as homogeneous patterns (smooth surfaces). Specifically, under an opaque pixel, there is an overlapping of the exponential decay in intensity from each edge (due to diffraction) that, in addition to the low contrast of the photoresist and the nonlinear interaction of photopolymerized features, can eventually trigger the emergence of a continuous polymerized structure.

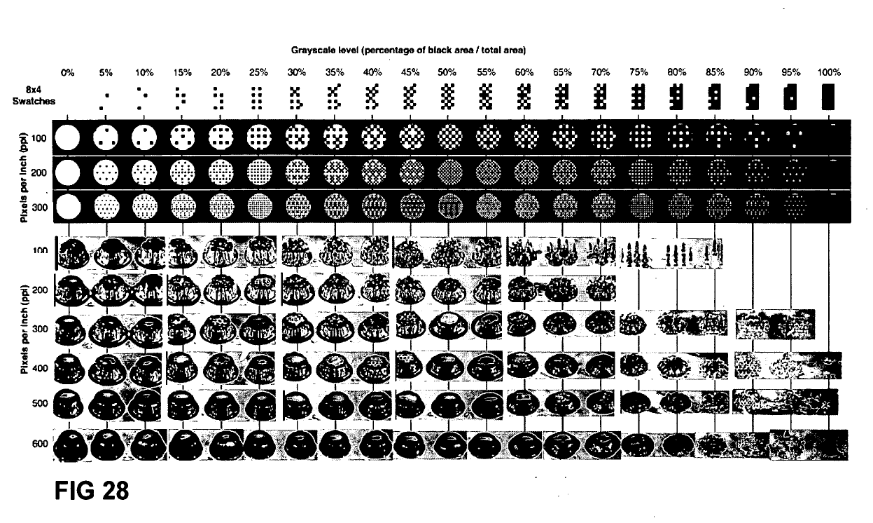

To control this nonlinear collective phenomenon, tiling pattern units or “swatches” are used as repetitive motifs to define areas that transmit the same level of UV intensity. Each swatch is a distinct array of pixels where the relative density of transparent to opaque pixels determines the average UV light intensity transmitted (see, e.g., FIG. 28).

Preferably, the device created is a microfluidic device that has a main channel with several constrictions that alternate with dead-end side microchannels.

In another example, curved surfaces may also be created by designing incremental grayscale tones in adjacent small areas. This may be accomplished because after the first exposure to UV light, the polymer at the surface is in a compliant gel-like state that can stick to itself during cleaning, smoothing the transitions between surfaces of similar heights. Moreover, semicircular microchannels have been generated by using swatches of 5×1 pixels that are further enlarged with graphic-design software.

In yet another example, 8×4 pixel swatches are combined for multilevel flat surfaces with 5×1 swatches. These may produce a microchannel with a zigzag structure that is modulated in the three x, y, and z directions.

Similarly, swatches with different hierarchical levels may be used to design complex micro fluidic devices. Typically, the first level defines the grayscale tones for simple geometries such as the ones considered in the previous examples, and the subsequent levels increase the degree of complexity. An illustration of this is an array of polymerized “horns” that is fabricated and used as a master for a microfluidic device that ejects monodisperse liquid droplets into air.

It should be noted that all of the patterns described herein may be combined to form a single microfluidic device. Further, all of the microstructures described herein may be combined into one microfluidic device.

Some of the advantages of the inventive method include (i) ease of design; (ii) fast turn-around times both for mask design and fabrication based solely on exposure times; (iii) low cost of transparency masks, i.e., about 15 US Dollars; and (iv) patterning of large areas and single structures simultaneously with topographic resolutions of tens of microns.

### 2. Detailed Description of Preferred Embodiments

Specific embodiments of the present invention will now be further described by the following, non-limiting examples which will serve to illustrate various features of significance. The examples are intended merely to facilitate an understanding of ways in which the present invention may be practiced and to further enable those of skill in the art to practice the present invention. Accordingly, the examples should not be construed as limiting the scope of the present invention.

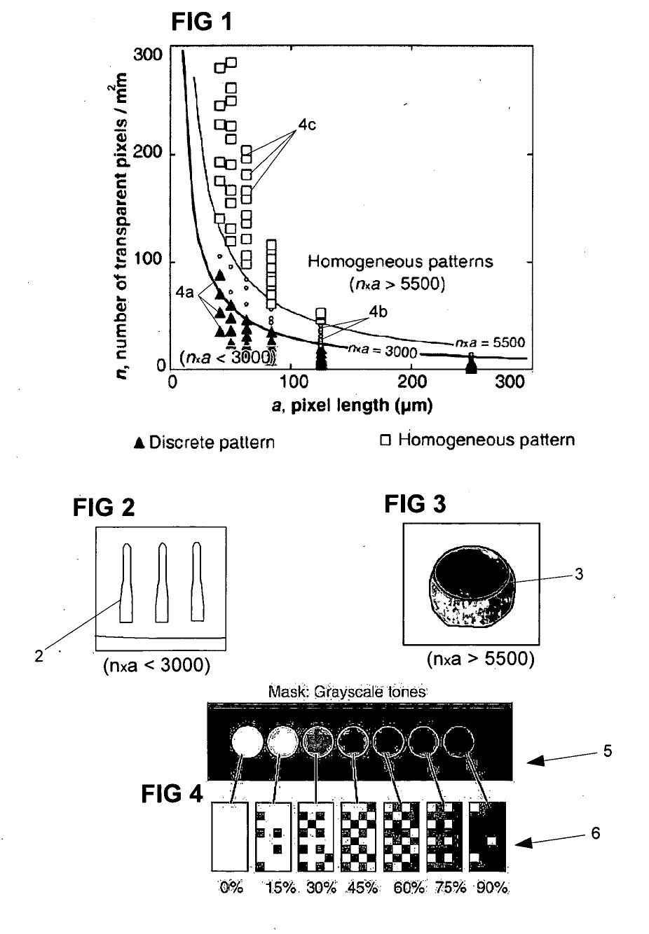

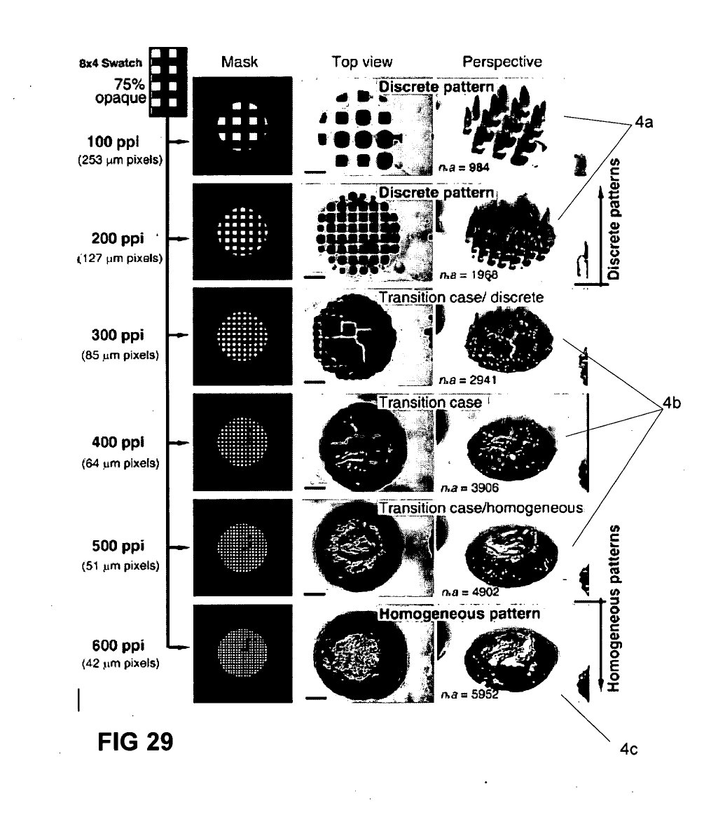

FIG. 1 shows a diagram of the morphology transition in an array of cylinders (2 mm diameter) that is created with masks patterned with variable pixel size and pixel density. A photoresistive adhesive polymerizes forming individual posts 4a (Δ) and 2 as shown in FIG. 2 or homogeneous macro surfaces 4c (□) and 3 as shown in FIG. 3 depending on the number of transparent pixels per unit area of the patterned mask (n) and the size of a pixel (a). The reference number 4b (∘) denotes transition cases between homogenous and discrete patterns. For further details see also FIG. 29. Interestingly, it was found that small individual posts (≈30 μm) generated with transparent pixels in swatches are vertical and form long threads, probably due to a lensing effect. Such complex geometries are useful for many applications such as to create tailored 3D flow patterns inside the microchannel to promote chaotic advection. Further, they may be used to create arbitrary cross sections in the microchannel that yield in plane velocity profiles different than Poiseuille flow for pressure driven systems. Finally, they may be used to modify the cross sectional distribution of the electric field in electro-osmotic flow to eliminate electric field constriction.

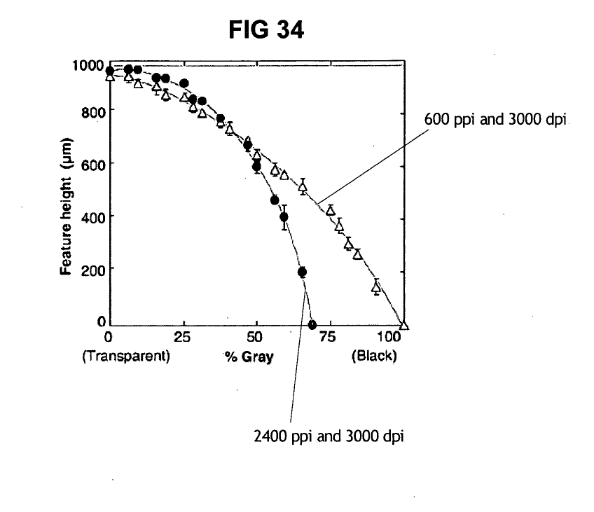

FIG. 4 shows a grayscale illustration 5 with corresponding pixel patterns or swatches 6. It should be noted that experimental data shows the correlation between the height of macro-surfaces and grayscale tone in two experiments (see, e.g., FIGS. 28 and 29, and graph shown in FIG. 34), with patterns at 600 ppi (pixels per inch) (•) and 2400 ppi (Δ) and in both cases at 3000 dpi (dots per inch) printing resolution. Pixels per inch, “ppi,” is used for pixel size when referring to the resolution of the pixilation process when converting theoretical grayscale into black and white pixels to distinguish it from the printing resolution or mask resolution that is given in “dpi” (dots per inch). The lines in FIG. 34 are a fit to guide the eye. The in-plane resolution is given by the size of the swatch used and by the minimum spacing required between features to avoid partial polymerization. Using 8×4 swatches at 2400 ppi (and 3000 dpi) the minimum area size that can be patterned is 42×84 μm². Below 2400 ppi, the optical resolution of the experimental photolithographic setup interferes with the fidelity of the patterns. It was discovered empirically that the optical adhesive polymerizes forming vertical “threads” of 1 to 2 μm diameter, which sets the ultimate in-plane resolution of the fabrication process with this material if higher resolution masks are employed. Using ink masks printed at 3000 dpi and the optical adhesive, the smallest reproducible feature fabricated was a microchannel of constant height of 60 μm±3 μm along the symmetry axis.

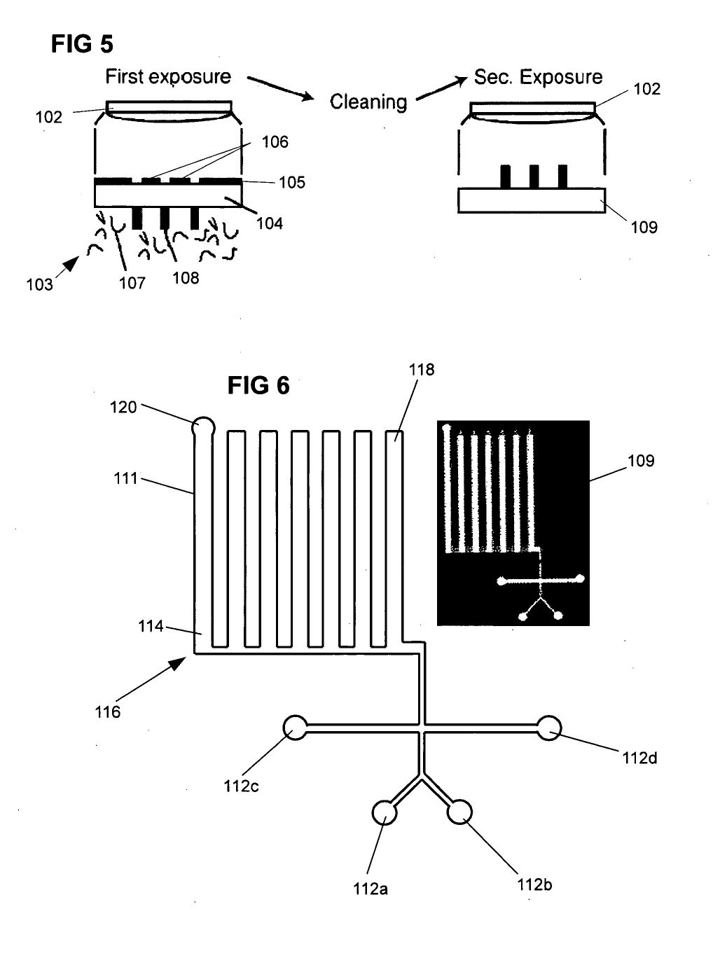

FIG. 5 shows one a method of making some of the microstructures of the present invention. Using grayscale fabrication, a photoresist material 103 is exposed to UV light 102 through a binary transparency mask 105. In between the mask 105 and the photoresist material 103 is preferably a glass slide 104. The mask 105 preferably has a plurality of transparent and opaque pixels which form patterns used to fabricate microstructures with modulated topography over large areas. Large groups of pixels or “swatches” are needed for more complex shapes. The photoresist material used is an optical adhesive 107 with low contrast γ≈0.55. Contrast is a measure of the ability of a resist to distinguish between transparent and opaque areas of a mask and typical photoresists have a contrast of 2 to 3. At least partial polymerization of the material 103 occurs to create polymerized microstructures 108. It should be noted that the photolithographic contrast is the maximum slope of the plot of development rate versus exposure dose on a logarithmic scale. The contrast of optical adhesion is calculated by collecting data on the following: 1) the calculation of the position of the polymerization front as a function of time; and 2) an accurate knowledge of the light intensity at the surface of the optical adhesive.

The transmittance of light through grayscale patterns becomes increasingly nonlinear as the pattern pixel size approaches the printing resolution of the mask. As will be discussed further below, the entire process needed to be calibrated instead of using higher resolution masks to increase pattern fidelity.

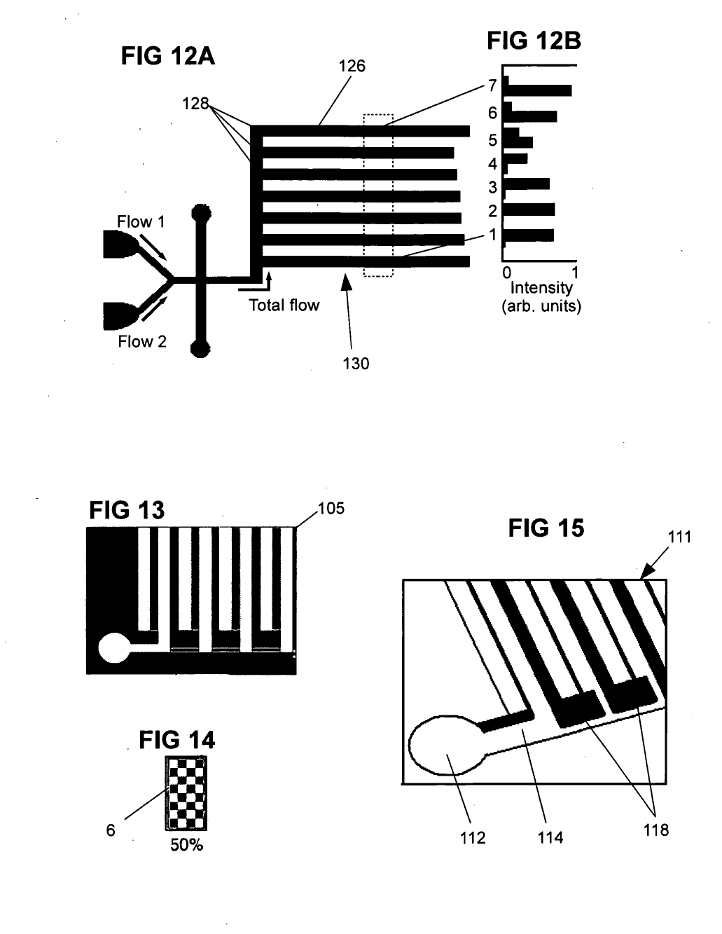

FIG. 6 shows an embodiment of the present invention including a multilevel microfluidic device 111 preferably used for the deterministic storage of liquid plugs using capillary forces. Replica molding is also used for the fabrication of this microfluidic device. First, a thiolene master or template 109 is created (see insert shown next to FIG. 6). This is done with grayscale transparency mask 105 as discussed above. However, the mask uses 8×4 swatches (see, e.g., FIGS. 8 and 9) of pixels. The swatches create in the device 111 at least one multilevel microchannel 114 that is able to harness capillarity forces and store fluid in a deterministic way (see, e.g., FIG. 12A).

The preferred microfluidic device or chip 111 has four inlets 112a-112d as shown in FIG. 6. These inlets 112a-d merge into the main microchannel 114. The microchannel 114 preferably includes topographic constrictions 116 that alternate with dead-end side microchannels 118. Preferably, at least one outlet 120 is provided on the chip 111. As best shown in FIGS. 10 and 11, each constriction 116 is designed to stop a priming flow through the main channel 114, using capillary forces until the previous side channel 118 is completely filled and a plug of liquid is stored. Consequently, this device 111 may be used to create libraries of liquid plugs with arbitrary concentrations of liquids, e.g., dilute chemicals.

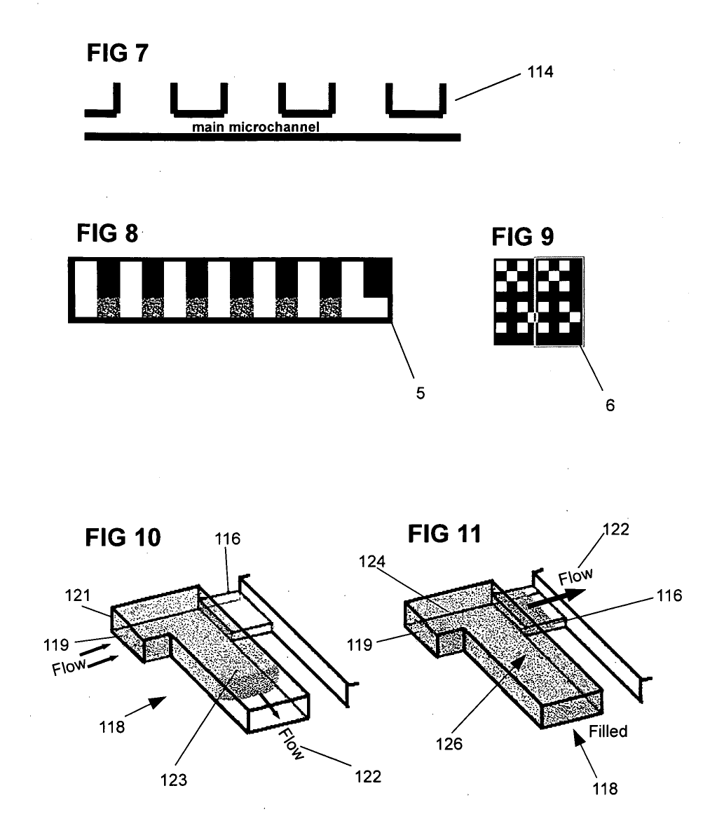

FIG. 7 shows a detail on a bottom of the device 111 including the main microchannel 114. FIG. 8 is a grayscale pattern 5 used to construct the microchannel 114. FIG. 9 is an 8×4 swatch 6, e.g., a 70% grayscale pattern, used for the constrictions 116.

FIG. 10 is a schematic showing the typical operation of the microfluidic device 111. A liquid is introduced through an inlet and moves along the main microchannel. It then comes to an inlet 119 to the side channel 118. The pressure that must be overcome by the moving the liquid front is higher at the constriction 116 than at the side microchannels 118, and, therefore, the side channels 118 fill first before the liquid moves on. The quantity of liquid contained in a channel is often referred to as a plug of liquid 126.

It should be noted that the maximum capillary force preventing a liquid front from wetting hydrophobic walls is proportional to the perimeter of the interface, and is given (if the microchannel is rectangular and all walls are hydrophobic) by F_{c}=γ cos(θ)×2(w+h), where γ is the surface tension of the liquid, θ is the contact angle (we assume the same contact angle for all walls), w is the width of the channel and h is the height of the channel. If a pressure ΔP is applied to the liquid plug 126 in order to move it, the advancing interface will be subject to a force proportional to the area of the interface F_{ad}=ΔP×(w×h). The plug starts moving when F_{ad}>F_{c} thus, F_{ad}/F_{c}>1, which can be expressed as: (w×h)/(w+h)>2γ cos(θ)/ΔP. If the height of the microchannel is reduced by a factor n, then

(w×h/n)/(w+h/n)=(w×h)/(n×w+h)<(w×h)/(w+h),∀n>1

and, therefore, the pressure threshold to start moving a liquid front in rectangular hydrophobic microchannels is higher in small channels or constrictions. Thus, as shown in FIG. 11, the liquid enters a constriction 116 only after filling the previous side channel.

As shown in FIG. 12A, deterministic combinatorial storage of fluidic libraries 130 is illustrated by using two syringe pumps simultaneously to deliver two different color dyes and to store them in closed compartments (side channels 118) of the device 111. The delivery rate of both dyes is ramped inversely, with 100% red and 0% blue at the beginning and 0% red and 100% blue at the end. The different combinatorial concentrations are stored passively in the different compartments. The external programmable syringe pumps introduce a red and blue dye through inlets 1 and 2, respectively, in FIG. 12A. Both flow rates are ramped with the same slope and opposite sign, thus maintaining a constant total flow rate through the main channel 114 throughout priming. The liquid with variable dye concentrations is stored sequentially in the side channels 118. This yielded an array 128 with a color gradient that varied within each side microchannel 118 and between microchannels. This illustration thus shows that it is possible for complex mixtures to be a) generated and stored in such a chip for applications such as chemotaxis experiments under zero-flow conditions, or b) dispersed in immiscible liquid forming droplets for combinatorial experiments and stored deterministically for subsequent analysis.

Referring now to FIGS. 13-15 another possible embodiment of the microfluidic device 111 is shown. As shown in FIG. 13, a grayscale pattern on a mask 105 is created. The mask 105 preferably is constructed using 8×4 swatches 6 like the one shown in FIG. 14. FIG. 15 shows a close-up of the device 111 created. The device 111 includes an inlet 112, a main microchannel 114, and a plurality of side channels 118.

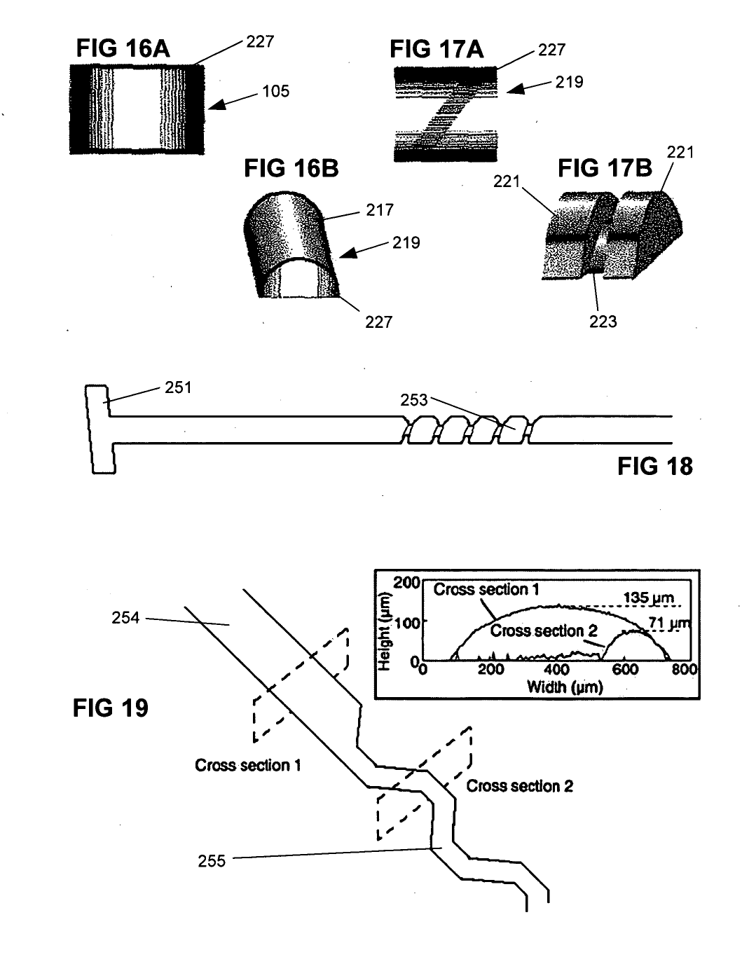

Referring to FIGS. 16A-17B, in this embodiment of the device 111, curved surfaces are generated with a single grayscale mask. For example, as shown in FIG. 16A, the mask 105 is created with first-level 5×1 swatches (arrays of 5×1 transparent and opaque pixels) that are elongated along the length of the microchannel to form lines 227. The complexity of the curved surface 227 is then increased with simple graphic operations such as stretching, rotating, and skewing (graphics software may be used here). For example, a second pattern of lines may be used to generate a microchannel of smaller diameter. Here, after a first pattern is created, a second pattern is created by skewing the first pattern by 30 degrees. Then, the second pattern is overlaid on top of the first pattern to obtain a semi-circular micro channel 219 with a semi-spiral ridge inside. The resulting two axis symmetric grayscale gradients end up defining curved sides of the microchannel as shown in FIG. 16B. In FIGS. 17A and 17B, the same type of patterns are then used to create a microchannel 223 of smaller diameter then the rest of the microchannel 221. The original is first skewed and overlaid on top of the patterns of the previous panel, rendering a single semi-spiral ridge. In the embodiment shown in FIG. 18, the patterns in FIGS. 16A-17B were repeated several times along the main channel to build a “T” main microchannel 251 with a semi-screw mixer 253. This is accomplished with a single mask.

In the example seen in FIG. 19, the mixing part of the “T” microchannel is modified to introduce simultaneous modulation in the x, y, and z directions (i.e., a so-called zigzag pattern 225). As shown by the inset cross-section, the channel 254 goes from a larger diameter to a smaller diameter. The minimum spacing between patterns necessary to generate such stepped flat surfaces is also the area required as a transition between steps, and can be calculated with the sidewall angle and the height difference between steps. A sidewall angle of approximately 85 degrees is created from medium-low grayscale tones. Grayscale tones close to the homogenization threshold generate surfaces with lower sidewall angles that may vary depending on the pattern.

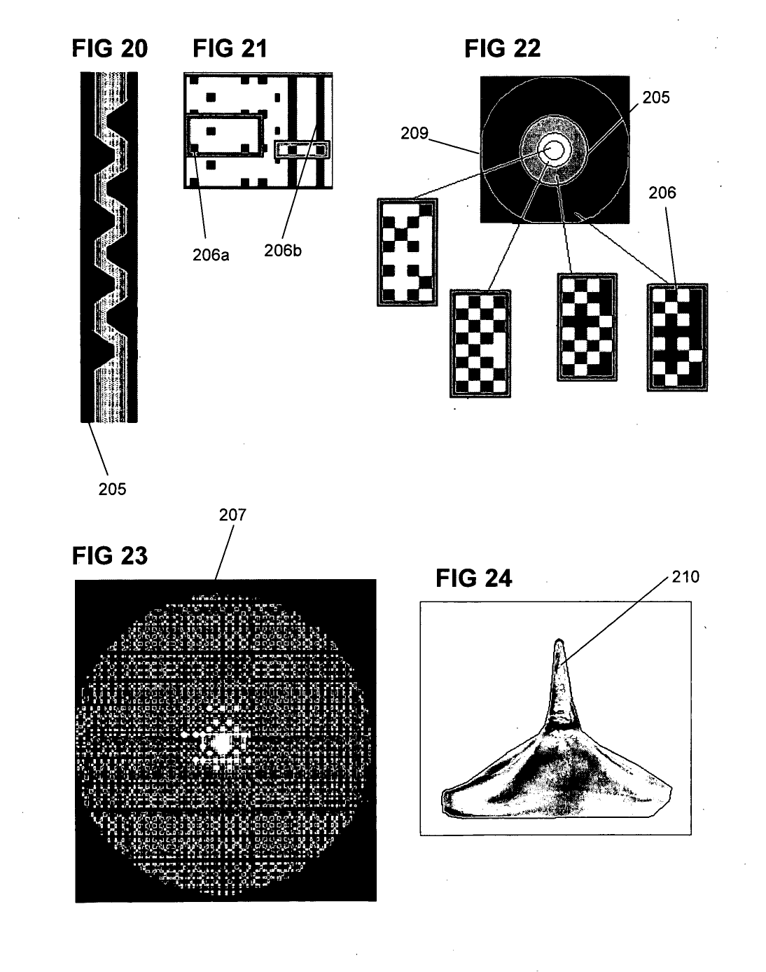

FIG. 20 shows a pattern 205 that may be used to create such a channel 254. FIG. 21 shows a detail of an 8×4 swatch 206a (10%) and a 5×1 swatch 206b (60%) used to make such a pattern master 205. As mentioned, once the method of the present invention has created a three dimensional microfluidic device, the device may be used to create libraries of liquid plugs with arbitrary concentrations of chemicals, cells, etc.

The homogenization phenomenon is further enhanced by designing a mask with an array of circles filled with different patterns to fabricate a combinatorial set of polymerized structures. Each circle in the mask may be tiled with a different 8×4 swatch (swatch formed by 8×4 pixels), that differ in either average “grayscale tone” (the ratio of transparent to opaque pixels where 0% is completely transparent and 100% completely opaque) or in pixel size. Again as shown in FIG. 1, it was discovered that there is a transition where binary patterns on the mask are transferred to the photoresist as homogeneous polymerized patterns, or discrete polymerized patterns where the pixel geometry is apparent (e.g., one post per pixel). Interestingly, this transition does not depend on pixel density but instead is found to occur for a critical value of the product of n×a, where n is the number of transparent pixels per unit area, and a is the side length of the pixel.

Specifically, if n×a>5500 μm per unit of patterned area (in mm²), the pattern is transferred as a homogeneous smooth surface (this condition may be referred to as the “grayscale homogenization threshold”). Further, if n×a<3000 μm/mm², it is transferred as a collection of discrete pixelated patterns (FIG. 2). Thus, while the relation between grayscale tone and polymerized feature height is reproducible, it may be complex to predict. Nevertheless, as shown in FIG. 34 a simple calibration method may be used to empirically determine this relation for a set of swatches and design microfluidic devices a posteriori. For example, each swatch produces a specific photopolymerized structure of a distinct height, and, therefore, they may be used as building blocks in a hierarchical design approach for the creation of complex polymerized patterns within the device. In this way, multilevel flat features can be easily fabricated by designing adjacent large areas with swatches of different grayscale tones.

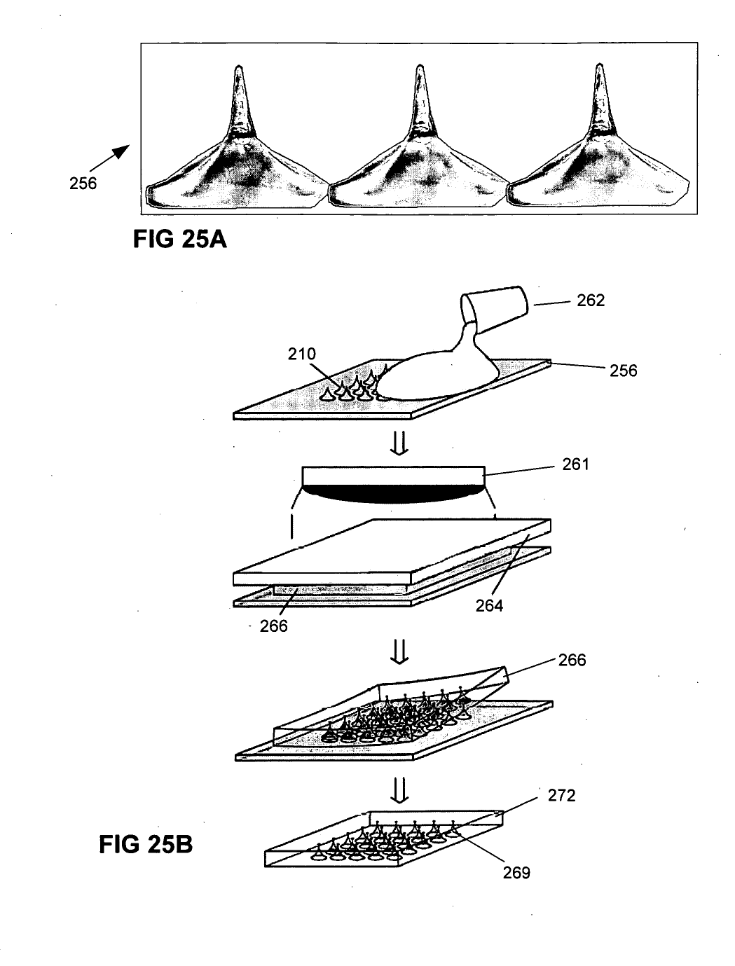

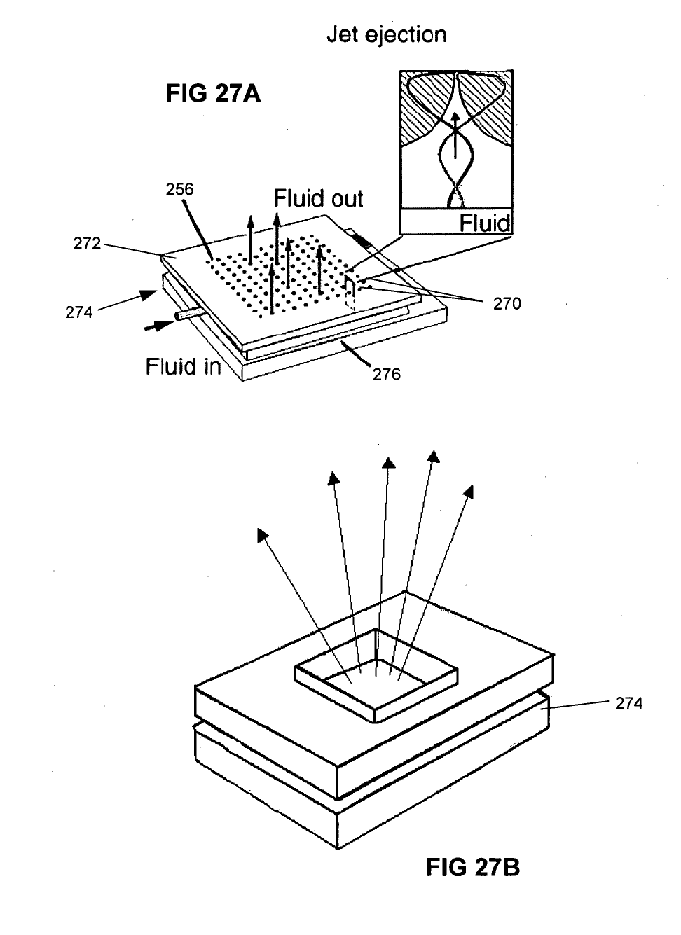

FIGS. 22-24, show how another embodiment of the present invention may be formed utilizing hierarchical patterning. FIG. 22 shows a compound of concentric circles 209 of different grayscale tones in pattern 205. The 8×4 swatches 206 below from left to right correspond to a 35%, 45%, 60%, and 65% grayscale tone. FIG. 23 shows a mask design 207 pixilated using first-level 8×4 swatches 206. First, a horn 210 is constructed from concentric circles 209 patterned with different tonalities of first-level grayscale 8×4 swatches. Such a single horn 210 is shown in FIG. 24. In any event, the circles 209 vary monotonically from black in the outer circle (1 mm outer diameter) to white in the inner circle (50 μm diameter), as shown in FIG. 22. Next, this design is used to define a second-level swatch, and apply it to pattern a large rectangle with the same repetitive motif as shown in FIG. 25A to create a master. Additional first-level swatches may be added to the design to generate multilevel micro channels or other curved surfaces. Alternatively, the master horn pattern 256 may be used to construct microfluidic ejectors 270, shown in FIG. 27A.

Fabrication of the ejectors 270 is as follows: an adhesive 262 is poured over the master 256, next a glass slide 264 with a thick membrane of polydimethylsiloxan (PDMS) 266 is pressed against the master 256 and the adhesive 262 is exposed to a UV light 261. When both sides are pressed together, the tips of the horns are inserted into the soft PDMS layer 266 to form an ejector plate 272. Thus, the horn cavities 269 created on one side of the sandwiched membrane end up in orifices that surface on the other side of the membrane. Next the completed membrane or ejector plate 272 is released from the master. The membrane with the horn cavities 269 connecting both sides is used as an ejector plate.

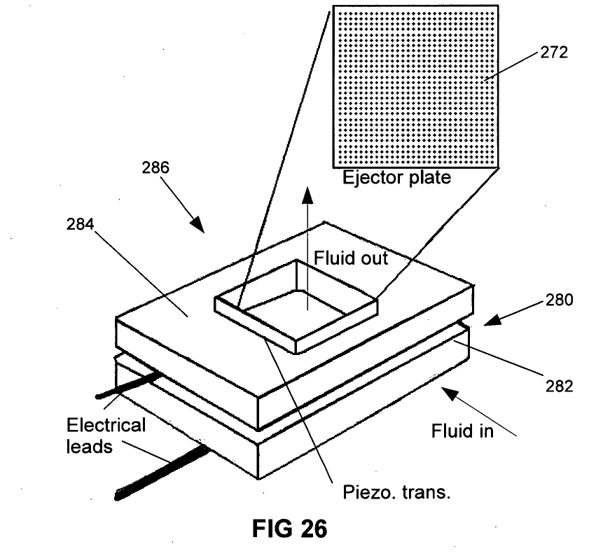

A prototype of an atomizer 274 with an ejector plate 272 is shown in FIG. 26. The plate 272 is mounted over a PDMS gasket 282 and piezoelectric actuator 284. These are then assembled between pieces of aluminum and polycarbonate to form a sandwich structure 286 around a fluid cavity, as shown in FIG. 26.

To operate the ejector, the fluid cavity is primed with water. A sinusoidal AC voltage signal is then generated by a function generator provided by Stanford Research Systems DS345 and an RF amplifier provided by T&C Power Conversion AG1020. When it is operated at a specific frequency (e.g. from 0.8 to 1.1 MHz), the piezoelectric transducer 276 produces standing acoustic waves that are focused by geometrical reflections within the horns, creating a pressure gradient that can be used for fluid jet ejection. The resulting micro fluidic device 274 may be used to eject liquids, such as water, through the thiolene nozzle orifices at ≈5 ml/min flow rate (see, e.g., FIGS. 27A and 27B). Moreover, the diameter of the nozzle orifices (40 μm) is well suited to cell manipulation via focused mechanical forces to enable various biophysical effects such as the uptake of small molecules and gene delivery and transfection. Additionally, the grayscale mask here may be designed to create nozzle orifices of different sizes for application to areas as diverse as mass spectrometry, fuel processing, manufacture of multilayer parts and circuits, and photoresist deposition without spinning.

FIG. 25A illustrates the result when the design of a single horn shown in FIG. 24 is used as a second-level swatch to pattern a large rectangular area (20×20 mm²). After fabrication, this swatch pattern may be used to generate an array of thiolene horns. As shown in FIG. 25B, these horns then may be used as a template to replicate repetitive cavities and form an ejector plate (see, e.g., FIG. 26).

FIG. 26 shows a microfluidic device including the ejector formed from the array of horns. FIG. 27A shows a schematic illustrating the operation of an ultrasonic atomizer created using a method of the present invention. Here fluid enters the chamber through a capillary. When the piezoelectric transducer is driven at a resonant frequency of the chamber, pressure wave focusing leads to ejection of jets of liquid. FIGS. 27A and 27B both show a demonstration of jet ejection with a microfluidic.

As shown in FIGS. 28 and 29, various pixels of varying sizes may be used to create a wide variety of swatches and ultimately microstructures. FIG. 28 shows the results of various experiments that have been conducted to determine homogeneous/discrete patterns and their relation with the size and number of transparent pixels. Note that here first level swatches are used to pattern 32 pattern intensities (‘tonalities’). Further, an array of grayscale binary masks of 2 mm circles are shown patterned with several grayscale tones. Swatches are also shown in the panels at different pixel sizes and densities, e.g., pixels per inch or ppi. The examples of thiolene polymerized patterns created with such masks are also shown.

FIG. 29 shows examples of the determination of a discrete pattern 4a, a transition case 4b, and a homogeneous pattern 4c in the case of 75% grayscale with varying ppi. It should be noted that n is the number of pixels per millimeter squared of pattern and a is the pixel size in micrometers.

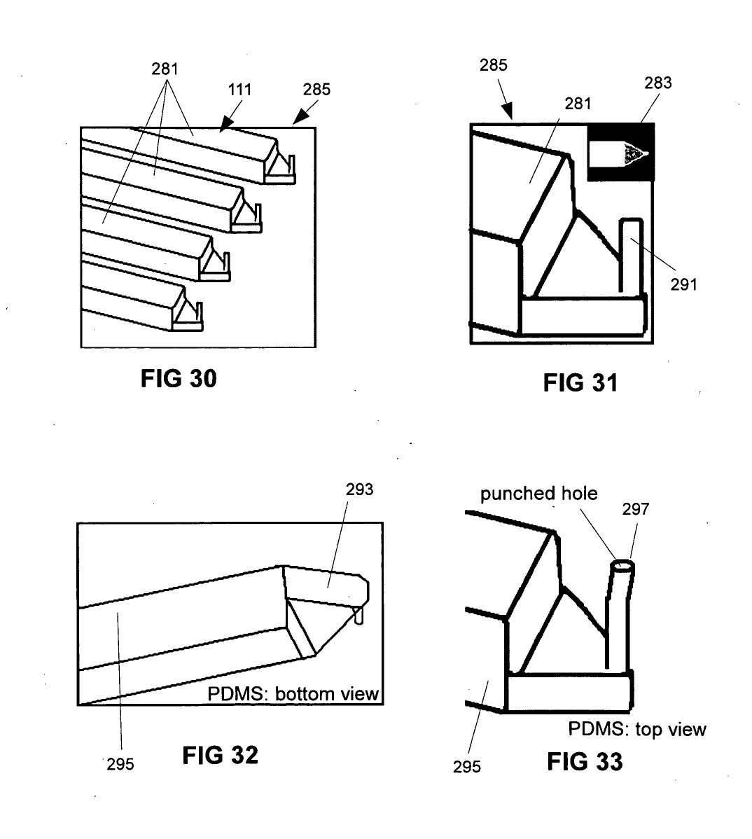

FIGS. 30-33, show yet another embodiment of a microfluidic device 111 of the present invention including various microstructures 281. FIGS. 30 and 31 show a master template of a microstructure and FIGS. 32-33 show replicas created from the template shown in FIGS. 30 and 31. The insert view in FIG. 31 shows a grayscale pattern 283 used to produce the microstructure 281. FIG. 30 shows a detail of the thiolene master pattern 285 showing the array of side microchannels 281. FIG. 31 shows a detail of an end of a side microchannel 281. The post 291 at the end of the micro channel 281 is used to create a cavity 293 on the PDMS replica 295. FIG. 32 shows a bottom view of a PDMS replica 295 created using the master 285. FIG. 33 shows that the previously discussed cavity may be used as a guide to introduce a thin metal tubing 297 and punch a small hole all the way through the PDMS and out to the exterior.

There are virtually innumerable uses for the present invention, all of which need not be detailed here. Additionally, all the disclosed embodiments can be practiced without undue experimentation. Further, although the best mode contemplated by the inventors of carrying out the present invention is disclosed above, practice of the present invention is not limited thereto. It will be manifest that various additions, modifications, and rearrangements of the features of the present invention may be made without deviating from the spirit and scope of the underlying inventive concept.

In addition, the individual components of the present invention discussed herein need not be fabricated from the disclosed materials, but could be fabricated from virtually any suitable materials. Moreover, the individual components need not be formed in the disclosed shapes, or assembled in the disclosed configuration, but could be provided in virtually any shape, and assembled in virtually any configuration. Furthermore, all the disclosed features of each disclosed embodiment can be combined with, or substituted for, the disclosed features of every other disclosed embodiment except where such features are mutually exclusive.

Further, although the concept of pattern homogenization for the fabrication of 3D structures is shown and described here using masking opaque/transparent motifs and UV light, the same concept could easily be accomplished using infrared light (thermal radiation) and a thermal-resist instead of UV light and a photoresist. Another additional possibility would be to use conventional lithography to create the motifs on a photoresist covering a silicon or glass wafer. The photoresist with the motifs would work as a mechanical mask for the fabrication of 3D structures on the wafers using wet or dry etching.

It is intended that the appended claims cover all such additions, modifications, and rearrangements. Expedient embodiments of the present invention are differentiated by the appended claims.

What is claimed is:

1. A three dimensional microfluidic device comprising:
a plurality of inlets;
a main microchannel having topographic constrictions and having fluid communication with the inlets; and
dead-end side channels with small orifices to allow gas to escape in fluid communication with the main microchannel.

2. The device of claim 1, further comprising at least one outlet in communication with the microchannel.

3. The device of claim 1, wherein each constriction is designed to stop priming flow through the main microchannel.

4. The device of claim 1, wherein the constrictions use capillary forces to move a liquid until a dead-end side channel is completely filled and a plug of liquid is stored therein.

5. The device of claim 1, wherein the device is used to create libraries of liquid plugs with arbitrary concentrations of chemicals.

6. The device of claim 1, wherein a liquid to be stored in the device is stored sequentially in the dead-end side channels.

7. The device of claim 1, wherein the device allows for complex chemical mixtures to be: generated and stored for applications such as chemotaxis experiments under zero-flow conditions; dispersed in immiscible liquid forming droplets for combinatorial experiments; or stored deterministically for subsequent analysis.

8. The device of claim 1, wherein the device is used in a remote location to sample water from a source.

9. The device of claim 1, wherein the device is designed to be primed passively with capillary forces.

10. The device of claim 1, wherein liquid in the different dead-end side channels corresponds to samples acquired sequentially with a time lag between them.

11. The device of claim 1, wherein biological cells are introduced in different side channels according to a distinct property.

12. A microfluidic device without any actuator that is capable of sorting liquid plugs chronologically and storing them comprising:
a main microchannel with a multitude of topographic constrictions;
at least two inlets that merge into the main microchannel;
side channels that are associated with the topographic constrictions and alternate with the inlets; and
one outlet in communication with the main microchannel.

13. The device of claim 12, wherein the device provides for a gradient of proteins across a direction perpendicular to at least two of the side channels.

14. The device of claim 12, wherein the device is used under zero gravity to handle liquid samples in space.

15. A microfluidic device for sorting and storing liquid plugs comprising:
a photoresist exposed to UV light through a binary transparency mask including an optical adhesive with low contrast y≈0.55 to promote partial polymerization in areas subject to diffracted light and to facilitate the transfer of discrete patterns from the mask as homogeneous patterns (smooth surfaces) to the photoresist.

16. The device of claim 15, wherein semicircular microchannels are generated by using swatches of 5×1 pixels that are enlarged with graphic-design software to form lines.

17. The device of claim 15, wherein complex curved surfaces in the microchannel are created with graphic software operations such as stretching, rotating and skewing.

18. The device of claim 15, further comprising a second microchannel of a smaller diameter that is semi-circular and includes a semi-spiral ridge inside.

19. The device of claim 15, wherein the microchannel has a zigzag structure that is modulated in an x, y and z direction.

20. The device of claim 15, wherein the microchannel has tailored 3D flow patterns inside to accomplish at least one of: promote chaotic advection, create arbitrary cross sections in the microchannel that yield in plane velocity profiles different than Poiseuille flow for pressure driven systems, and modify the cross sectional distribution of an electric field.
